(19) United States
(12) Patent Application Publication
(10) Pub. No.: US 2025/0274097 A1
(43) Pub. Date: Aug. 28, 2025

(54) ACOUSTIC WAVE DEVICE WITH SUPPRESSED SHEAR HORIZONTAL MODE

(71) Applicant: SKYWORKS SOLUTIONS, INC., Irvine, CA (US)

(72) Inventors: Yuya Hiramatsu, Neyagawa-Shi (JP); Tomoya Komatsu, Irvine, CA (US); Kyohei Kobayashi, Otsu-Shi (JP)

(21) Appl. No.: 19/050,365

(22) Filed: Feb. 11, 2025

Related U.S. Application Data
(60) Provisional application No. 63/558,437, filed on Feb. 27, 2024.

(51) Int. Cl. H03H 9/02; H03H 9/145; H03H 9/25

(52) U.S. Cl. CPC H03H 9/02866; H03H 9/14541; H03H 9/25

(57) ABSTRACT

Aspects and embodiments disclosed herein include an acoustic wave device comprising a substrate, an interdigital transducer (IDT) electrode disposed on the substrate and configured to generate an acoustic wave in response to an electrical signal, the IDT electrode including a lower layer and an upper layer, a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.

### CROSS-REFERENCE TO RELATED APPLICATIONS

This application claims priority under 35 U.S.C. § 119 (e) to U.S. Provisional Patent Application Ser. No. 63/558,437, titled “ACOUSTIC WAVE DEVICE WITH SUPPRESSED SHEAR HORIZONTAL MODE,” filed Feb. 27, 2024, the entire content of which is incorporated herein by reference for all purposes.

### BACKGROUND

### Field

Aspects and embodiments of the present disclosure relate to electronic systems, and in particular, to a filter for use in radio frequency (RF) electronics.

### Description of the Related Technology

Filters are used in radio frequency (RF) communication systems to allow signals to pass through at discreet frequencies but reject any frequency outside of the specified range. An acoustic wave filter, which is used widely in the wireless communication field, can include a plurality of resonators arranged to filter a radio frequency signal. Example acoustic wave filters include surface acoustic wave (SAW) filters and/or bulk acoustic wave (BAW) filters. A film bulk acoustic resonator filter is an example of a BAW filter. Acoustic wave filters can be implemented in radio frequency electronic systems. For instance, filters in a radio frequency front end of a mobile phone can include acoustic wave filters. A plurality of acoustic wave filters can be arranged as a multiplexer. For example, two surface acoustic wave filters can be arranged as a duplexer.

Examples of RF communication systems with one or more filter modules include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In accordance with one aspect, there is provided an acoustic wave device comprising a substrate, an interdigital transducer (IDT) electrode disposed on the substrate and configured to generate an acoustic wave in response to an electrical signal, the IDT electrode including a lower layer and an upper layer, a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.

In some embodiments, the lower layer of the IDT electrode is formed of at least one of molybdenum (Mo), copper (Cu), titanium (Ti), tungsten (W), or platinum (Pt).

In some embodiments, the lower layer of the IDT electrode has a relative thickness l₁/λ of about 5.0% to 11.5%.

In some embodiments, the dielectric layer is formed of silicon dioxide (SiO₂).

In some embodiments, the height of the dielectric layer has a relative thickness h/λ of about 15% to 45%.

In some embodiments, the high velocity layer is formed of at least one of silicon nitride, silicon oxynitride, aluminum nitride, aluminum oxide, or diamond.

In some embodiments, the thickness of the high velocity layer is about 3% to 5% of the height of the dielectric layer.

In some embodiments, the high velocity layer is located at about 40% to 50% of the height of the dielectric layer.

In some embodiments, the high velocity layer has a Young's modulus higher than about 60 GPa.

In accordance with another aspect, there is provided a radio frequency module comprising a packaging board configured to receive a plurality of components, an acoustic wave device implemented on the packaging board, the acoustic wave device including a substrate, an interdigital transducer (IDT) electrode disposed on the substrate and configured to generate an acoustic wave in response to an electrical signal, the IDT electrode including a lower layer and an upper layer, a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.

In some embodiments, the radio frequency module is a front-end module.

In some embodiments, the lower layer of the IDT electrode is formed of at least one of molybdenum (Mo), copper (Cu), titanium (Ti), tungsten (W), or platinum (Pt).

In some embodiments, the lower layer of the IDT electrode has a relative thickness l₁/λ of about 5.0% to 11.5%.

In some embodiments, the dielectric layer is formed of silicon dioxide (SiO₂).

In some embodiments, the height of the dielectric layer has a relative thickness h/λ of about 15% to 45%.

In some embodiments, the high velocity layer is formed of at least one of silicon nitride, silicon oxynitride, aluminum nitride, aluminum oxide, or diamond.

In some embodiments, the thickness of the high velocity layer is about 3% to 5% of the height of the dielectric layer.

In some embodiments, the high velocity layer is located at about 40% to 50% of the height of the dielectric layer.

In some embodiments, the high velocity layer has a Young's modulus higher than about 60 GPa.

In accordance with another aspect, there is provided a mobile device comprising an antenna configured to receive a radio frequency signal, and a front end system configured to communicate with the antenna, the front end system including an acoustic wave device including a substrate, an interdigital transducer (IDT) electrode disposed on the substrate and configured to generate an acoustic wave in response to an electrical signal, the IDT electrode including a lower layer and an upper layer, a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.

In some embodiments, the lower layer of the IDT electrode is formed of at least one of molybdenum (Mo), copper (Cu), titanium (Ti), tungsten (W), or platinum (Pt).

In some embodiments, the lower layer of the IDT electrode has a relative thickness l₁/λ of about 5.0% to 11.5%.

In some embodiments, the dielectric layer is formed of silicon dioxide (SiO₂).

In some embodiments, the height of the dielectric layer has a relative thickness h/λ of about 15% to 45%.

In some embodiments, the high velocity layer is formed of at least one of silicon nitride, silicon oxynitride, aluminum nitride, aluminum oxide, or diamond.

In some embodiments, the thickness of the high velocity layer is about 3% to 5% of the height of the dielectric layer.

In some embodiments, the high velocity layer is located at about 40% to 50% of the height of the dielectric layer.

In some embodiments, the high velocity layer has a Young's modulus higher than about 60 GPa.

### BRIEF DESCRIPTION OF THE DRAWINGS

FIG. 1 is a cross-sectional view of a portion of a surface acoustic wave (SAW) resonator;

FIG. 2 is a schematic view of a portion of a ladder filter;

FIG. 3 illustrates a frequency response of parameters of the ladder filter of FIG. 2;

FIG. 4 illustrates various design parameters of a SAW resonator;

FIG. 5 illustrates an example block diagram of an acoustic wave device according to the present disclosure;

FIG. 6 illustrates a frequency response of various parameters of a ladder filter including resonators including a dielectric layer including high velocity layer;

FIG. 7A illustrates a simulation result of measuring SH-spurious intensity of an acoustic wave device without the high velocity layer;

FIG. 7B illustrates a simulation result of measuring SH-spurious intensity of an acoustic wave device according to an embodiment of the present disclosure;

FIG. 8A illustrates a measurement result of admittance/conductance of an acoustic wave device according to an embodiment of the present disclosure depending on the thickness of the high velocity layer;

FIG. 8B illustrates a measurement result of SH-mode intensity of an acoustic wave device according to an embodiment of the present disclosure depending on the thickness of the high velocity layer;

FIG. 9A illustrates a basic resonator admittance (dB) of an acoustic wave device according to an embodiment of the present disclosure;

FIG. 9B illustrates a basic resonator conductance (dB) of an acoustic wave device according to an embodiment of the present disclosure;

FIG. 9C illustrates a basic resonator DMS S21 of an acoustic wave device according to an embodiment of the present disclosure;

FIG. 10A is a schematic block diagram of an electronic module that includes a filter;

FIG. 10B is a schematic block diagram of an electronic module that includes a filter;

FIG. 11 shows an example of a ladder filter in which an acoustic wave device according to the present disclosure may be implemented;

FIG. 12 is a block diagram of one example of a filter module that includes one or more acoustic wave devices according to embodiments of the present disclosure;

FIG. 13 is a block diagram of one example of a front-end module that include one or more filter modules including acoustic wave devices according to embodiments of the present disclosure; and

FIG. 14 is a block diagram of one example of a wireless device including the front-end module of FIG. 13.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments disclosed herein include RF filters built on a piezoelectric substrate, for example LiNbO₃ or LiTaO₃, and exhibiting a ladder structure including series and parallel resonators. The resonators may include surface acoustic wave (SAW) resonators including interleaved interdigital transducer (IDT) electrodes that are covered by a dielectric film, for example SiO₂, or a combination of dielectric films, for example SiO₂ and Si₃N₄.

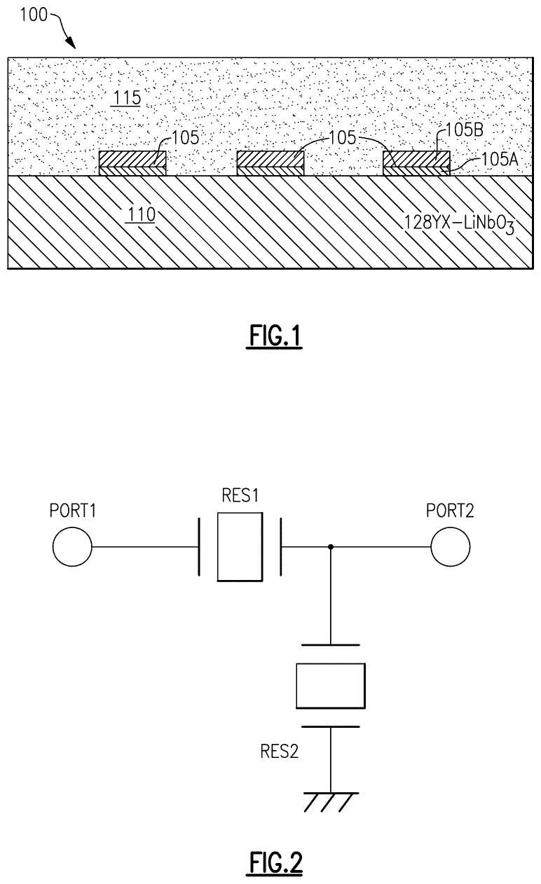

FIG. 1 is a simplified cross-sectional view of a portion of a surface acoustic wave (SAW) resonator, indicated generally at 100. The SAW resonator 100 includes a plurality of IDT electrodes 105 disposed on a piezoelectric substrate 110. The piezoelectric substrate 110 may consist of or comprise, for example, LiNbO₃ or LiTaO₃, or another piezoelectric material. In the specific embodiment illustrated in FIG. 1, the piezoelectric substrate 110 is 128YX cut LiNbO₃. The plurality of IDT electrodes 105 and the piezoelectric substrate 110 are covered by a layer of dielectric material 115, for example, silicon dioxide (SiO₂). In any of the embodiments disclosed herein, the layer of dielectric material 115 may be covered by a second layer of dielectric material, for example, silicon nitride (Si₃N₄) that may provide for passivation and frequency trimming of the SAW resonator 100. This second layer of dielectric material is omitted from the figures for sake of simplicity. The IDT electrodes 105 are illustrated in FIG. 1 as including a lower layer 105A and an upper layer 105B. The lower layer 105A may include or consist of, for example, tungsten or molybdenum and the upper layer 105B may include or consist of, for example, aluminum. Although the IDT electrodes illustrated in the other figures of this application are illustrated as including a single material layer for simplicity, is to be appreciated that the IDT electrodes in any of the embodiments disclosed herein may be formed of a single material or of multiple layers of different materials.

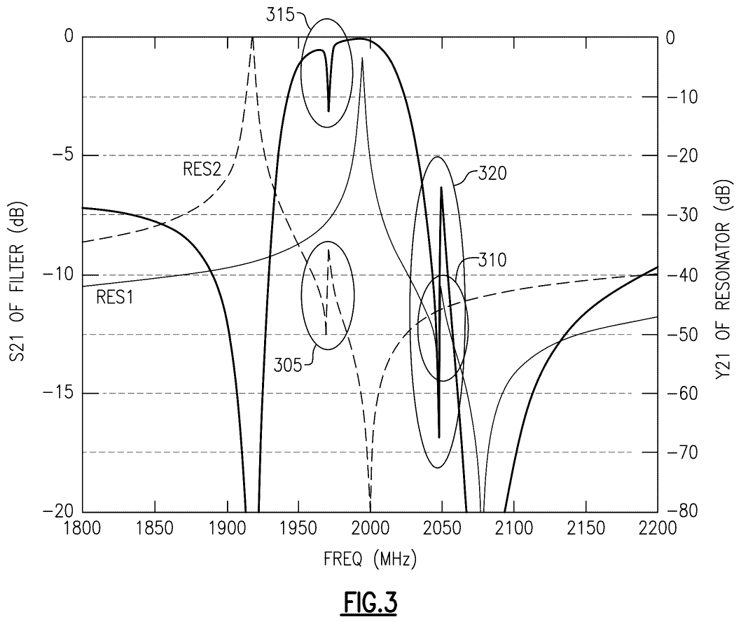

FIG. 2 is a schematic view of a portion of a ladder filter. Multiple SAW resonators may be assembled together to form a ladder filter. The portion of the ladder filter includes a single series resonator RES1 positioned in series between input and output ports PORT1 and PORT2 of the portion of the ladder filter and a single parallel resonator RES2 electrically connected in parallel between a terminal of the series resonator RES1 and ground. The resonators RES1 and RES2 may have different resonance and antiresonance frequencies, with series resonator RES1 typically having a higher resonance frequency than the resonance frequency of parallel resonator RES2, as well as a higher anti-resonance frequency than the anti-resonance frequency of parallel resonator RES2.

FIG. 3 illustrates a frequency response of parameters of the ladder filter of FIG. 2. As shown in FIG. 3, a simulation of the performance of the resonators RES1 and RES2 and of the portion of the ladder filter is provided. The curves of the impedance parameters Y21 of the longitudinal wave (Rayleigh) vibrational modes of the resonators RES1 and RES2 exhibit discontinuities, indicated at 305 and 310, due to the presence of shear wave vibrational modes generated during operation. The discontinuities in the impedance parameter curves of the resonators RES1 and RES2 lead to discontinuities, indicated at 315 and 320, in the transmission parameter S21 from PORT1 to PORT2 of the ladder filter. Discontinuities 315 and 320 are undesirable in that they degrade performance of the ladder filter.

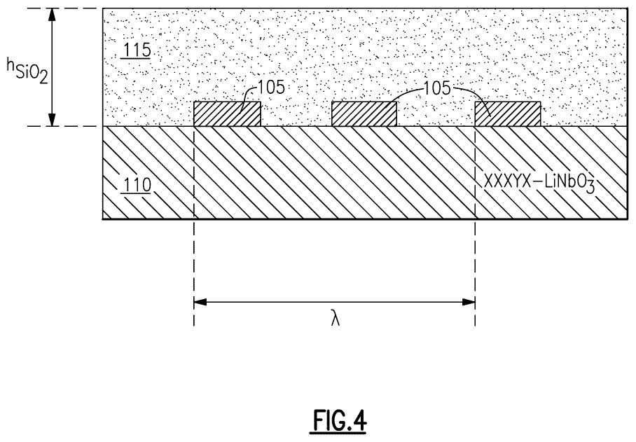

FIG. 4 illustrates design parameters of a SAW resonator. Various parameters of SAW resonators that may be adjusted include the spacing between the IDT electrodes 105, which in turn defines the wavelength 2 of the resonant frequency of the resonator, the height hSiO₂ of the dielectric layer 115, and the cut angle of the piezoelectric crystal substrate. These parameters are illustrated in FIG. 4, with the cut angle of the piezoelectric crystal substrate designated as “xxx”.

The height hSiO₂ of the dielectric layer 115 affects the temperature coefficient of frequency (TCF) of a SAW resonator and the coupling coefficient k2 between the IDT electrodes 105 and the piezoelectric substrate 110. The relative height hSiO₂/h of the dielectric layer 115 is thus typically selected to achieve desired values for these parameters in a SAW resonator. Once the relative height hSiO₂/λ of the dielectric layer 115 is selected, the cut angle xxx of the piezoelectric crystal substrate may be selected to minimize the intensity of the shear wave spurious signal. A cut angle of about 129 degrees may be selected to minimize shear wave spurious signals in an embodiment of a SAW resonator having a relative height hSiO₂/λ of the dielectric layer of between 25% and 30%, whereas a shallower cut angle, for example of about 127 degrees, may be appropriate for suppressing shear wave spurious signals in an embodiment of a SAW resonator having a relative height hSiO₂/λ of the dielectric layer of greater than about 35%.

For the purpose of achieving higher performance of the acoustic wave filter, the shear wave spurious signals should be further suppressed.

FIG. 5 illustrates an example block diagram of an acoustic wave device 500 according to the present disclosure. The acoustic wave device 500 according to an embodiment of the present disclosure may include a substrate 110, an interdigital transducer (IDT) electrode 105, a dielectric layer 115, and a high velocity layer 510.

The acoustic wave device 500 according to an embodiment may be a surface acoustic wave (SAW) filter or a boundary wave filter. Particularly, temperature compensated surface acoustic wave (TCSAW) filters are widely used for high performance RF modules. Reliability of TCSAWs play quite an important role in ensuring final module product reliability.

The substrate 110 may be formed of lithium niobate (LiNbO₃). The substrate 110 may provide a medium in which an acoustic wave can propagate. The substrate 110 may be a piezoelectric crystal substrate having a cut angle of 128 degrees.

The IDT electrode 105 may be disposed on the substrate 110. The IDT electrode 105 may be configured to generate an acoustic wave in response to an electrical signal. The IDT electrode 105 may include a lower layer 105A and an upper layer 105B. According to an embodiment, the lower layer 105A may be formed of at least one of molybdenum (Mo), copper (Cu), titanium (Ti), tungsten (W), or platinum (Pt). The upper layer 105B may be formed of at least one of aluminum (Al), copper (Cu), silver (Ag), or gold (Au).

The thickness of the lower layer 105A may reduce the effect of the SH mode. For example, if the lower layer 105A of the IDT electrode 105 is thick, there is a point at which SH coupling is zero before it shifts out of the band. More specifically, as the lower layer 105A of the IDT electrode 105 gets thicker, the SH mode moves to a lower frequency range. According to an embodiment, the lower layer 105A may have a relative thickness l₁/λ of 5.0˜11.5%. λ denotes the wavelength of the resonant frequency of the acoustic wave device.

The dielectric layer 115 may have a height h and may be formed to cover at least a part of the substrate 110 and the IDT electrode 105. The dielectric layer 115 may be formed of silicon dioxide (SiO₂). The height h of the dielectric layer 115 may be defined as the distance between the upper surface of the substrate 110 and the upper surface of the dielectric layer 115. The height h of the dielectric layer 115 may have an impact on the reduced SH mode. According to an embodiment, the dielectric layer 115 may have a relative thickness h/λ of about 15% to 45%.

The high velocity layer 510 may be embedded within the dielectric layer 115. The high velocity layer 510 may be arranged above the IDT electrode 105 and in parallel to the upper surface of the substrate 110. For example, the dielectric layer 115 may be split into an upper layer and a lower layer by the high velocity layer 510.

The high velocity layer 510 may exhibit a higher acoustic velocity than the dielectric layer 115. More specifically, the high velocity layer 510 may be formed of at least one of silicon nitride, silicon oxynitride, aluminum nitride, aluminum oxide, or diamond. By adding a layer of a material having a higher acoustic velocity than the dielectric material within the dielectric layer 115, the frequency at which the discontinuity in the impedance parameter curve of a SAW resonator occurs due to the generation of shear wave spurious modes may be shifted.

According to an embodiment, the thickness t of the high velocity layer 510 may be about 3% to 5% of the height h of the dielectric layer 115. According to an embodiment, the high velocity layer 510 may be located between about 40% to 50% of the height h of the dielectric layer 115. The high velocity layer 510 may have a Young's modulus higher than about 60 GPa.

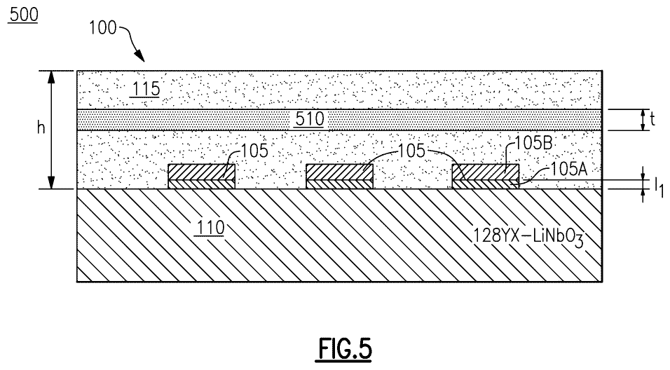

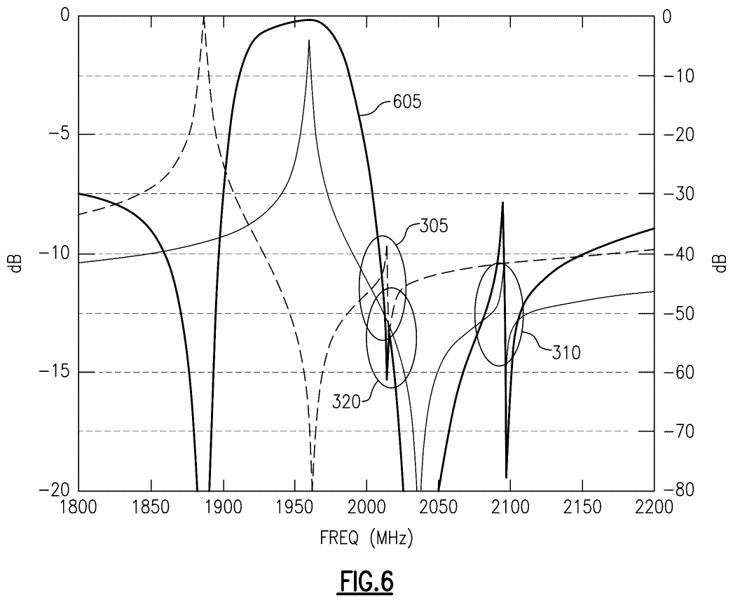

FIG. 6 illustrates the impact on filter performance of a filter similar to that illustrated in FIG. 2 when a high velocity layer 510 is included in the dielectric layers 115 of the acoustic wave device 500. Comparing the transmission parameter curve 605 illustrated in FIG. 6 to that illustrated in FIG. 3, it is apparent that due to the shifts in the frequencies at which the discontinuities 305, 310 in the impedance parameter curves of the resonators occur, the discontinuity in the impedance parameter curve indicated at 315 in FIG. 3 has been eliminated and the discontinuity indicated at 320 in FIG. 3 has been significantly reduced in magnitude. Moreover, any of the discontinuities shown in FIG. 3 may be shifted in frequency effectively out of the passband of the acoustic wave device 500.

The discontinuity 310 in the longitudinal mode impedance parameter curve of a resonator may correspond to a resonance in a shear wave vibration mode in the resonator. As illustrated in FIG. 6, performance of a ladder filter including SAW resonators may be improved by increasing the frequency difference between the antiresonance frequencies of the longitudinal wave vibration modes (Rayleigh mode) of the resonators and the resonance frequencies of the shear wave vibration modes of the resonators.

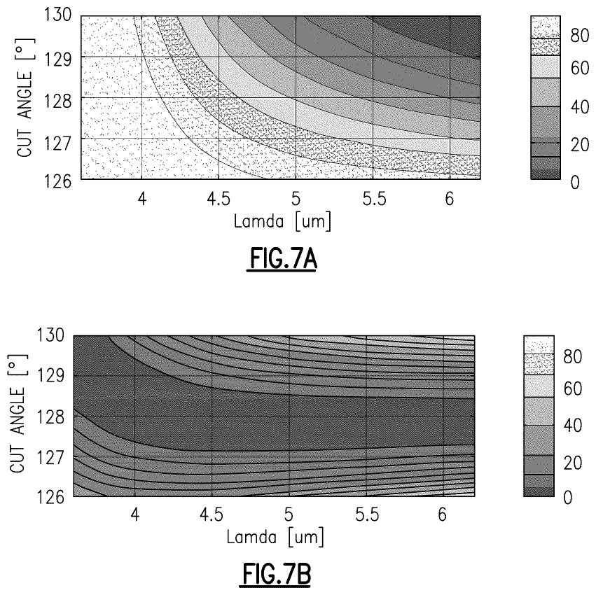

FIGS. 7A and 7B illustrate a simulation result of measuring SH-spurious intensity of the acoustic wave device according to an embodiment of the present disclosure. FIG. 7A shows the SH-spurious intensity of the acoustic wave device without the high velocity layer, and FIG. 7B shows the SH-spurious intensity of the acoustic wave device with the high velocity layer. As can be seen from FIG. 7B, at a certain point of cut angle, a low SH-spurious intensity is obtained throughout the whole range of λ.

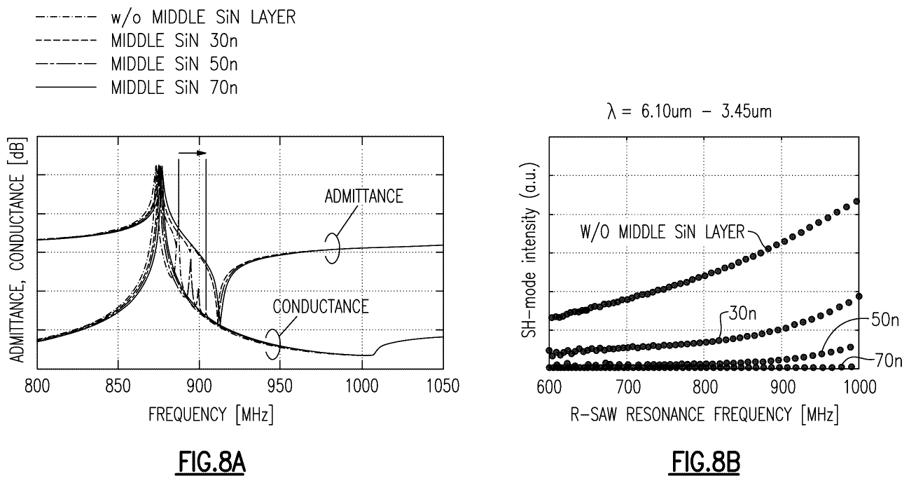

FIGS. 8A and 8B illustrate a measurement result of admittance/conductance and SH-mode intensity of the acoustic wave device depending on the thickness of the high velocity layer. As can be seen from FIG. 8B, the SH mode is not detected for the acoustic wave device having the high velocity layer with a thickness of 70 nm. As shown in FIG. 8B, the thicker high velocity layer provides for less intensity in the SH mode. More specifically, the SH frequency is shifted upwards by inserting the high velocity layer, and therefore the SH mode intensity becomes significantly lower.

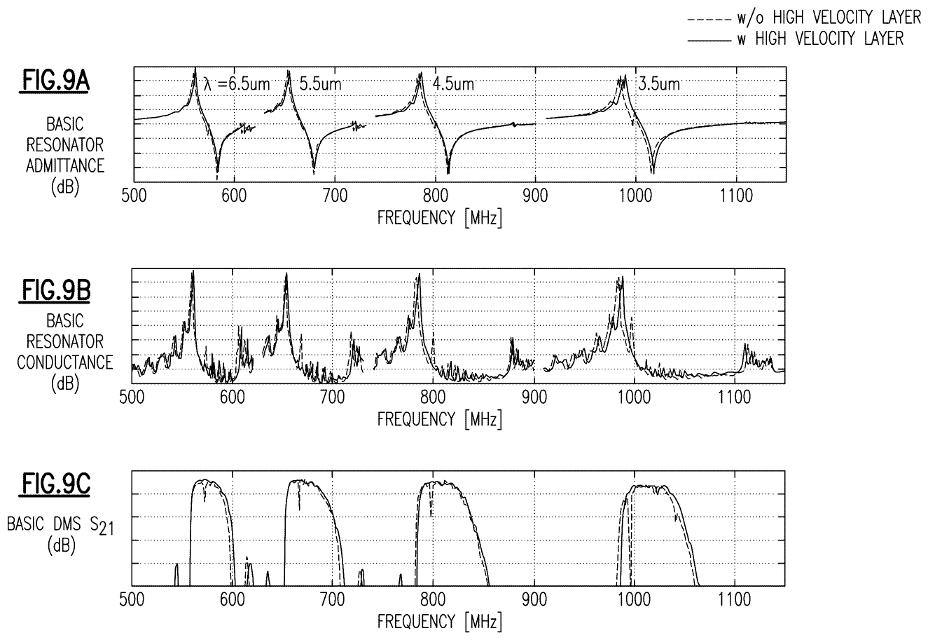

FIG. 9A illustrates a basic resonator admittance (dB) of the acoustic wave device. FIG. 9B illustrates a basic resonator conductance (dB) of the acoustic wave device. FIG. 9C illustrates a basic resonator DMS S21 of the acoustic wave device. As can be seen from FIGS. 9A, 9B, and 9C, the frequency response of parameters of the acoustic wave device are significantly improved.

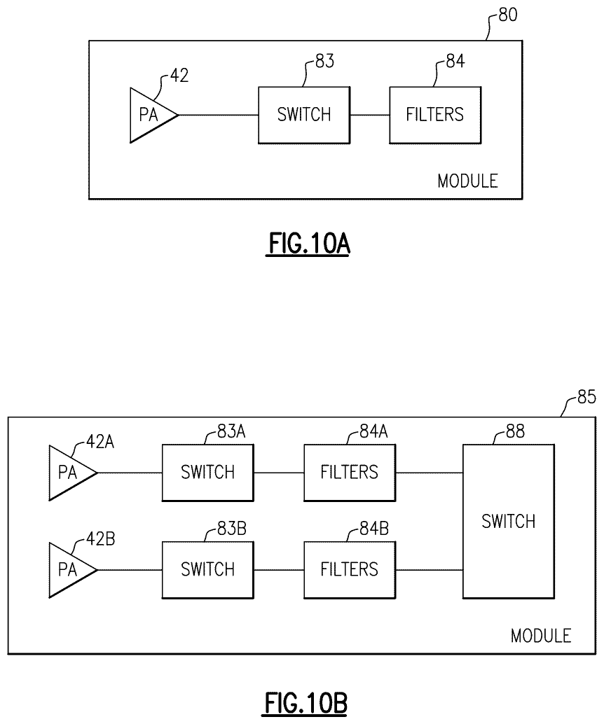

The acoustic wave device (resonator) discussed herein can be implemented in a variety of packaged modules. Some example packaged modules will now be discussed in which any suitable principles and advantages of the filters discussed herein can be implemented. FIGS. 10A and 10B are schematic block diagrams of illustrative packaged modules according to certain embodiments.

FIG. 10A is a schematic block diagram of a module 80 that includes a power amplifier 42, a switch 83, and filters 84 in accordance with one or more embodiments. The module 80 can include a package that encloses the illustrated elements. The power amplifier 42, a switch 83, and filters 84 can be disposed on the same packaging substrate. The packaging substrate can be a laminate substrate, for example. The switch 83 can be a multi-throw radio frequency switch. The switch 83 can electrically couple an output of the power amplifier 42 to a selected filter of the filters 84. The filters 84 can include any suitable number of surface acoustic wave filters. One or more filters of the filters 84 can be implemented in accordance with any suitable principles and advantages disclosed herein.

FIG. 10B is a schematic block diagram of a module 85 that includes power amplifiers 42A and 42B, switches 83A and 83B, and filters 84A and 84B in accordance with one or more embodiments, and an antenna switch 88. One or more filters of the filters 84A and/or 84B can be implemented in accordance with any suitable principles and advantages disclosed herein. The additional RF signal path includes an additional power amplifier 42B, and additional switch 83B, and additional filters 84B. The different RF signal paths can be associated with different frequency bands and/or different modes of operation (e.g., different power modes, different signaling modes, etc.).

As discussed above, communications devices, such as mobile phones and the like, use filters and sub-systems incorporating filters (such as duplexers, diplexers, and the like) to separate signals in different frequency bands, such as transmission and reception signals, for example.

FIG. 11 shows an example of a filter 1100 which multiple SAW resonators (acoustic wave devices) as disclosed herein may be combined. FIG. 11 shows an RF ladder filter 1100 including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW devices as disclosed herein.

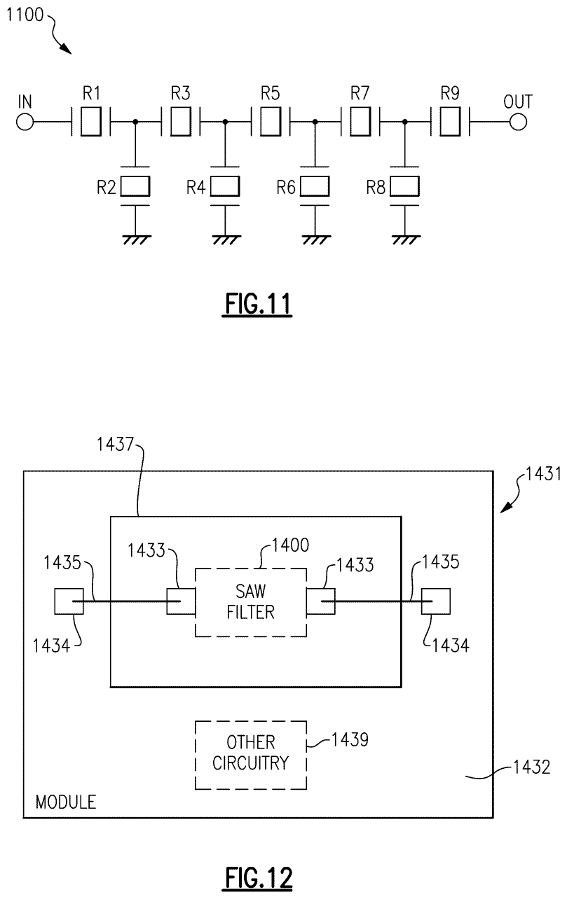

Moreover, examples and embodiments of SAW devices discussed herein can be implemented in a variety of packaged modules. Some example packaged modules will now be discussed in which any suitable principles and advantages of the SAW resonators discussed herein can be implemented. FIGS. 12, 13, and 14 are schematic block diagrams of illustrative packaged modules and devices according to certain embodiments.

As discussed above, the acoustic wave devices, for example SAW devices, can be used in SAW radio frequency (RF) filters. In turn, a SAW RF filter using one or more surface acoustic wave elements, such as the SAW RF filter 1100 of FIG. 11, may be incorporated into and packaged as a module that may ultimately be used in an electronic device, such as a wireless communications device, for example. FIG. 12 is a block diagram illustrating one example of a module 1431 including a SAW filter 1400. The SAW filter 1400 may be implemented on one or more die(s) 1437 including one or more connection pads 1433. For example, the SAW filter 1400 may include a connection pad 1433 that corresponds to an input contact for the SAW filter and another connection pad 1433 that corresponds to an output contact for the SAW filter. The packaged module 1431 includes a packaging substrate 1432 that is configured to receive a plurality of components, including the die 1437. A plurality of connection pads 1434 can be disposed on the packaging substrate 1432, and the various connection pads 1433 of the SAW filter die 1437 can be connected to the connection pads 1434 on the packaging substrate 1432 via electrical connectors 1435, which can be solder bumps or wirebonds, for example, to allow for passing of various signals to and from the SAW filter 1400. The module 1431 may optionally further include other circuitry die 1439, for example, one or more additional filter(s), amplifiers, pre-filters, modulators, demodulators, down converters, and the like, as would be known to one of skill in the art of semiconductor fabrication in view of the disclosure herein. In some embodiments, the module 1431 can also include one or more packaging structures to, for example, provide protection and facilitate easier handling of the module 1431. Such a packaging structure can include an overmold formed over the packaging substrate 1432 and dimensioned to substantially encapsulate the various circuits and components thereon.

Various examples and embodiments of the SAW filter 1400 can be used in a wide variety of electronic devices. For example, the SAW filter 1400 can be used in an antenna duplexer, which itself can be incorporated into a variety of electronic devices, such as RF front-end modules and communication devices.

Referring to FIG. 13, there is illustrated a block diagram of one example of a front-end module 1540, which may be used in an electronic device such as a wireless communications device (e.g., a mobile phone) for example. The front-end module 1540 includes an antenna duplexer 1550 having a common node 1541, an input node 1545, and an output node 1547. An antenna 1560 is connected to the common node 1541.

The antenna duplexer 1550 may include one or more transmission filters 1500a connected between the input node 1545 and the common node 1541, and one or more reception filters 1500b connected between the common node 1541 and the output node 1547. The passband(s) of the transmission filter(s) are different from the passband(s) of the reception filters. Examples of the SAW filter 1400 can be used to form the transmission filter(s) 1500a and/or the reception filter(s) 1500b. An inductor or other matching component 1543 may be connected at the common node 1541.

The front-end module 1540 further includes a transmitter circuit 1549 connected to the input node 1545 of the duplexer 1550 and a receiver circuit 1551 connected to the output node 1547 of the duplexer 1550. The transmitter circuit 1549 can generate signals for transmission via the antenna 1560, and the receiver circuit 1551 can receive and process signals received via the antenna 1560. In some embodiments, the receiver and transmitter circuits are implemented as separate components, as shown in FIG. 13, however, in other embodiments these components may be integrated into the same transceiver circuit or module. As will be appreciated by those skilled in the art, the front-end module 1540 may include other components that are not illustrated in FIG. 13 including, but not limited to, switches, electromagnetic couplers, amplifiers, processors, and the like.

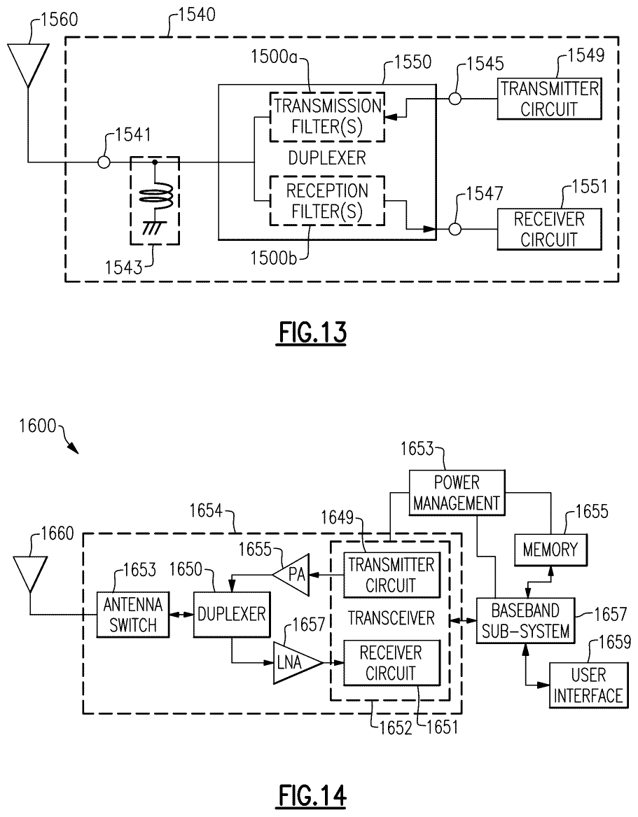

FIG. 14 is a block diagram of one example of a wireless device 1600 including an antenna duplexer 1650, such as the antenna duplexer 1550 shown in FIG. 13. The wireless device 1600 can be a cellular phone, smart phone, tablet, modem, communication network or any other portable or non-portable device configured for voice or data communication. The wireless device 1600 can receive and transmit signals from the antenna 1660. The wireless device includes an embodiment of a front-end module 1654 similar to that discussed above with reference to FIG. 13. The front-end module 1654 includes the duplexer 1650, as discussed above. In the example shown in FIG. 14 the front-end module 1654 further includes an antenna switch 1653, which can be configured to switch between different frequency bands or modes, such as transmit and receive modes, for example. The antenna switch 1653 may be positioned between the duplexer 1650 and the antenna 1660; however, in other examples the duplexer 1650 may be positioned between the antenna switch 1653 and the antenna 1660. In other examples the antenna switch 1653 and the duplexer 1650 can be integrated into a single component.

The front-end module 1654 includes a transceiver 1652 that is configured to generate signals for transmission or to process received signals. The transceiver 1652 can include the transmitter circuit 1649, which can be connected to the input node of the duplexer 1650, and the receiver circuit 1651, which can be connected to the output node of the duplexer 1650, in a similar manner as shown in the example of FIG. 13.

Signals generated for transmission by the transmitter circuit 1649 are received by a power amplifier (PA) module 1655, which amplifies the generated signals from the transceiver 1652. The power amplifier module 1655 can include one or more power amplifiers. The power amplifier module 1655 can be used to amplify a wide variety of RF or other frequency-band transmission signals. For example, the power amplifier module 1655 can receive an enable signal that can be used to pulse the output of the power amplifier to aid in transmitting a wireless local area network (WLAN) signal or any other suitable pulsed signal. The power amplifier module 1655 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 1655 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 14, the front-end module 1654 may further include a low noise amplifier (LNA) module 1657, which amplifies received signals from the antenna 1660 and provides the amplified signals to the receiver circuit 1651 of the transceiver 1652.

The wireless device 1600 of FIG. 14 further includes a power management sub-system 1653 that is connected to the transceiver 1652 and manages the power for the operation of the wireless device 1600. The power management system 1653 can also control the operation of a baseband sub-system 1657 and various other components of the wireless device 1600. The power management system 1653 can include, or can be connected to, a battery (not shown) that supplies power for the various components of the wireless device 1600. The power management system 1653 can further include one or more processors or controllers that can control the transmission of signals, for example. In one embodiment, the baseband sub-system 1657 is connected to a user interface 1659 to facilitate various input and output of voice and/or data provided to and received from the user. The baseband sub-system 1657 can also be connected to memory 1655 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

### Applications

Some of the embodiments described above have provided examples in connection with wireless devices or mobile phones. However, the principles and advantages of the embodiments can be used for any other systems or apparatus that have needs for power amplifiers.

Such filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An acoustic wave device comprising:
a substrate;
an interdigital transducer (IDT) electrode disposed on the substrate and configured to generate an acoustic wave in response to an electrical signal, the IDT electrode including a lower layer and an upper layer;
a dielectric layer having a height and formed to cover at least a part of the substrate and the IDT electrode; and
a high velocity layer embedded within the dielectric layer, the high velocity layer arranged above the IDT electrode and in parallel to an upper surface of the substrate, the high velocity layer being configured to provide a higher acoustic velocity than the dielectric layer.

2. The acoustic wave device of claim 1 wherein the lower layer of the IDT electrode is formed of at least one of molybdenum (Mo), copper (Cu), titanium (Ti), tungsten (W), or platinum (Pt).

3. The acoustic wave device of claim 1 wherein the lower layer of the IDT electrode has a relative thickness l₁/λ of about 5.0% to 11.5%.

4. The acoustic wave device of claim 1 wherein the dielectric layer is formed of silicon dioxide (SiO₂).

5. The acoustic wave device of claim 1 wherein the height of the dielectric layer has a relative thickness h/λ of about 15% to 45%.

6. The acoustic wave device of claim 1 wherein the high velocity layer is formed of at least one of silicon nitride, silicon oxynitride, aluminum nitride, aluminum oxide, or diamond.

7. The acoustic wave device of claim 1 wherein the thickness of the high velocity layer is about 3% to 5% of the height of the dielectric layer.

8. The acoustic wave device of claim 1 wherein the high velocity layer is located at about 40% to 50% of the height of the dielectric layer.

9. The acoustic wave device of claim 1 wherein the high velocity layer has a Young's modulus higher than about 60 GPa.

10. A radio frequency module comprising:
a packaging board configured to receive a plurality of components;
an acoustic wave device implemented on the packaging board, the acoustic wave device including a substrate, an interdigital transducer (IDT) electrode disposed on the substrate and configured to generate an acoustic wave in response to an electrical signal, the IDT electrode including a lower layer and an upper layer; a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.

11. The radio frequency module of claim 10 wherein the radio frequency module is a front-end module.

12. The radio frequency module of claim 10 wherein the lower layer of the IDT electrode is formed of at least one of molybdenum (Mo), copper (Cu), titanium (Ti), tungsten (W), or platinum (Pt).

13. The radio frequency module of claim 10 wherein the lower layer of the IDT electrode has a relative thickness l₁/λ of about 5.0% to 11.5%.

14. The radio frequency module of claim 10 wherein the dielectric layer is formed of silicon dioxide (SiO₂).

15. The radio frequency module of claim 10 wherein the height of the dielectric layer has a relative thickness h/λ of about 15% to 45%.

16. The radio frequency module of claim 10 wherein the high velocity layer is formed of at least one of silicon nitride, silicon oxynitride, aluminum nitride, aluminum oxide, or diamond.

17. The radio frequency module of claim 10 wherein the thickness of the high velocity layer is about 3% to 5% of the height of the dielectric layer.

18. The radio frequency module of claim 10 wherein the high velocity layer is located at about 40% to 50% of the height of the dielectric layer.

19. The radio frequency module of claim 10 wherein the high velocity layer has a Young's modulus higher than about 60 GPa.

20. A mobile device comprising:
an antenna configured to receive a radio frequency signal; and
a front end system configured to communicate with the antenna, the front end system including an acoustic wave device including a substrate, an interdigital transducer (IDT) electrode disposed on the substrate and configured to generate an acoustic wave in response to an electrical signal, the IDT electrode including a lower layer and an upper layer, a dielectric layer having a height and formed to cover at least a part of the substrate and the IDT electrode, and a high velocity layer embedded within the dielectric layer, the high velocity layer arranged above the IDT electrode and in parallel to an upper surface of the substrate, the high velocity layer being configured to provide a higher acoustic velocity than the dielectric layer.
